(19) United States
(12) Patent Application Publication
(10) Pub. No.: US 2023/0247766 A1
(43) Pub. Date: Aug. 3, 2023

(54) ELECTRONIC APPARATUS, ROBOT, AND MOTION STAGE

(71) Applicant: SEIKO EPSON CORPORATION, Tokyo (JP)

(72) Inventors: Mitsumi KISHIDA, SHIOJIRI-SHI (JP); Yutaka ARAKAWA, SUWA-GUN HARA-MURA (JP); Tomoaki TAKAHASHI, MATSUMOTO-SHI (JP); Yuichiro TSUYUKI, MATSUMOTO-SHI (JP)

(21) Appl. No.: 18/102,723

(22) Filed: Jan. 29, 2023

(30) Foreign Application Priority Data
Jan. 31, 2022 (JP) 2022-012894

(51) Int. Cl. H05K 1/18; B25J 9/00; B25J 17/00

(52) U.S. Cl. CPC H05K 1/181; B25J 9/0009; B25J 17/00; H05K 2201/0129; F16M 11/08

(57) ABSTRACT

An electronic apparatus includes an electronic component including a laminated body in which an intermediate layer is disposed between first and second substrates, the laminated body including a first side surface, a second side surface connected to one side of the first side surface, and a third side surface connected to the other side of the first side surface, a first terminal disposed on the first side surface of the first substrate, a second terminal disposed on the first side surface of the second substrate, and a recessed section that is positioned between the first and second terminals and that is recessed from the first side surface, a wiring substrate disposed to face the first side surface and a thermosetting adhesive that is located between the wiring substrate and the electronic component and that mechanically and electrically connects the wiring substrate and the electronic component to each other.

The present, application is based on, and claims priority from JP Application Serial Number 2022-012894, filed Jan. 31, 2022, the disclosure of which is hereby incorporated by reference herein in its entirety.

### BACKGROUND

### 1. Technical Field

The present disclosure relates to an electronic apparatus, a robot, and a motion stage.

### 2. Related Art

For example, the mounting structure described in JP-A-2021-145041 includes a flexible wiring substrate, a non-flexible component, a connecting section that connects the flexible wiring substrate and the non-flexible component, and a protective resin that seals the connecting section. Further, a through hole is formed in the flexible wiring substrate, and the protective resin is supplied through the through hole.

However, in the mounting structure of JP-A-2021-145041, when the flexible wiring substrate and the non-flexible component are connected to each other using a thermosetting adhesive as the connecting section, air present in a gap between the flexible wiring substrate and the non-flexible component expands in a heating process, and bubbles are generated in the thermosetting adhesive. Therefore, there is a possibility that the bonding strength and the electrical reliability are lowered.

### SUMMARY

An electronic apparatus according to the present disclosure includes an electronic component including a laminated body in which an intermediate layer is disposed between a first substrate and a second substrate, the laminated body including a first side surface, a second side surface connected to one side of the first side surface, and a third side surface connected to the other side of the first side surface, a first terminal disposed on the first side surface of the first substrate, a second terminal disposed on the first side surface of the second substrate, and a recessed section located between the first terminal and the second terminal and recessed from the first side surface; a wiring substrate disposed facing the first side surface; and a thermosetting adhesive that is located between the wiring substrate and the electronic component and that mechanically and electrically connects the wiring substrate and the electronic component to each other, wherein the recessed section extends along the first side surface and one end of the recessed section opens on the second side surface and the other end of the recessed section opens on the third side surface.

A robot of the present disclosure includes at least one joint and an electronic apparatus for driving the joint wherein the electronic apparatus includes: an electronic component including a laminated body in which an intermediate layer is disposed between a first substrate and a second substrate, the laminated body including a first side surface, a second side surface connected to one side of the first side surface, and a third side surface connected to the other side of the first side surface, a first terminal disposed on the first side surface of the first substrate, a second terminal disposed on the first side surface of the second substrate, and a recessed section located between the first terminal and the second terminal and recessed from the first side surface; a wiring substrate disposed facing the first side surface; and a thermosetting adhesive that is located between the wiring substrate and the electronic component and that mechanically and electrically connects the wiring substrate and the electronic component to each other, wherein the recessed section extends along the first side surface and one end of the recessed section opens on the second side surface and the other end of the recessed section opens on the third side surface.

A motion stage of the present disclosure includes a base; a movable section connected to the base; and an electronic apparatus configured to move the movable section with respect to the base, wherein the electronic apparatus includes: an electronic component including a laminated body in which an intermediate layer is disposed between a first substrate and a second substrate, the laminated body including a first side surface, a second side surface connected to one side of the first side surface, and a third side surface connected to the other side of the first side surface, a first terminal disposed on the first side surface of the first substrate, a second terminal disposed on the first side surface of the second substrate, and a recessed section located between the first terminal and the second terminal and recessed from the first side surface; a wiring substrate disposed facing the first side surface; and a thermosetting adhesive that is located between the wiring substrate and the electronic component and that mechanically and electrically connects the wiring substrate and the electronic component to each other, wherein the recessed section extends along the first side surface and one end of the recessed section opens on the second side surface and the other end of the recessed section opens on the third side surface.

### BRIEF DESCRIPTION OF THE DRAWINGS

FIG. 1 is a plan view showing a piezoelectric motor according to a first embodiment of the disclosure.

FIG. 2 is a cross-sectional view taken along line A-A in FIG. 1.

FIG. 3 is a cross-sectional view taken along line B-B in FIG. 1.

FIG. 4 is a cross-sectional view taken along line C-C in FIG. 1.

FIG. 5 is a perspective view illustrating a first side surface of a piezoelectric actuator.

FIG. 6 is a plan view illustrating a drive state of the piezoelectric actuator.

FIG. 7 is a plan view illustrating a drive state of the piezoelectric actuator.

FIG. 8 is a plan view illustrating a bonding section between a wiring substrate and the piezoelectric actuator.

FIG. 9 is a cross-sectional view illustrating a bonding method of the wiring substrate and the piezoelectric actuator.

FIG. 10 is a cross-sectional view illustrating a bonding method of the wiring substrate and the piezoelectric actuator.

FIG. 11 is a cross-sectional view illustrating a bonding method of the wiring substrate and the piezoelectric actuator.

FIG. 12 is a cross-sectional view illustrating an electronic apparatus according to a second embodiment.

FIG. 13 is a perspective view illustrating a first side surface of a piezoelectric actuator according to a third embodiment.

FIG. 14 is a perspective view showing a modification of the piezoelectric actuator.

FIG. 15 is a plan view showing a modification of the piezoelectric actuator.

FIG. 16 is a plan view showing a modification of the piezoelectric actuator.

FIG. 17 is a perspective view illustrating a robot according to a fourth embodiment.

FIG. 18 is a plan view showing a motion stage according to a fifth embodiment.

### DESCRIPTION OF EMBODIMENTS

Hereinafter, an electronic apparatus, a robot, and a motion stage according to the present disclosure will be, described in detail based on suitable embodiments illustrated in the accompanying drawings.

### First Embodiment

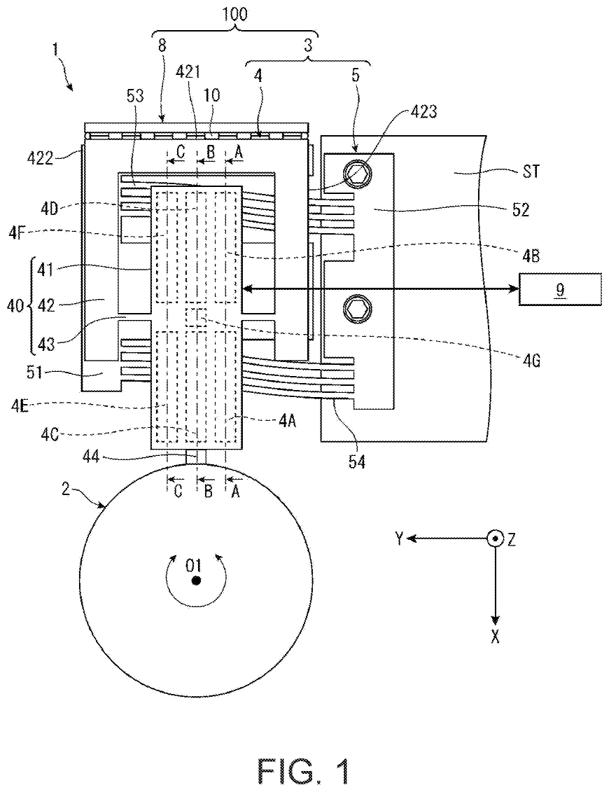

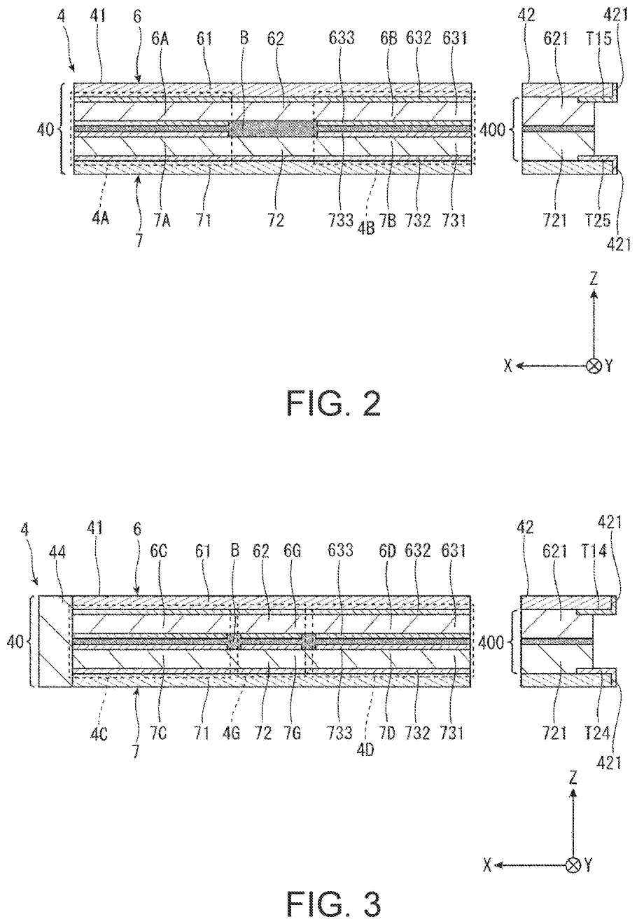

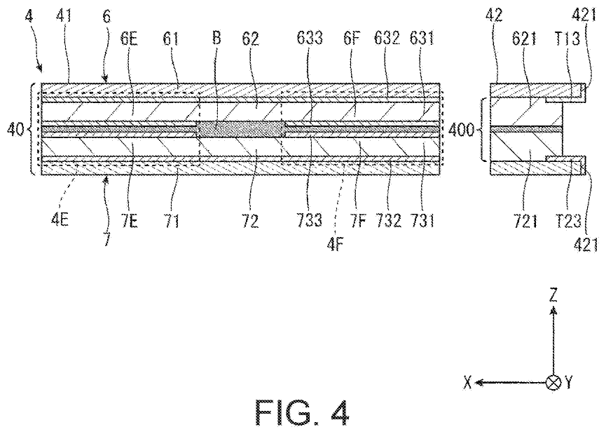

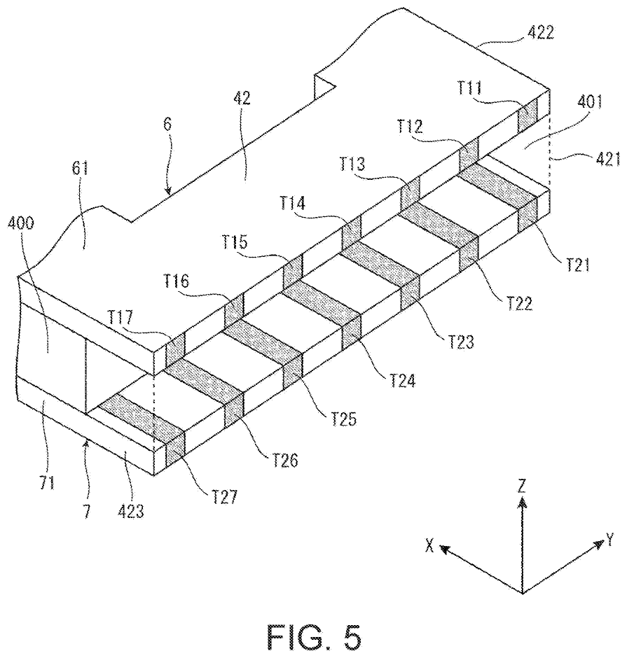

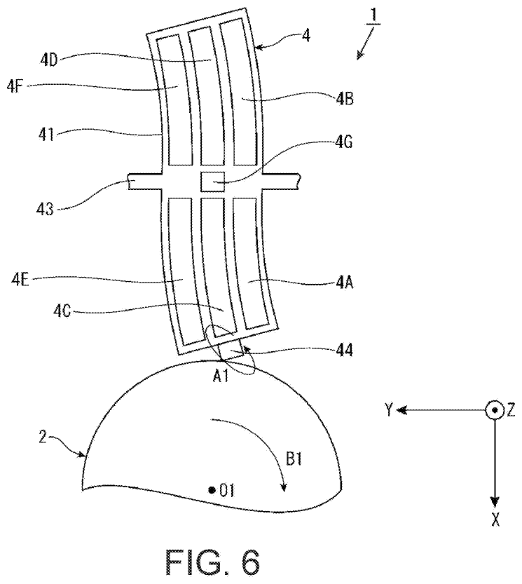

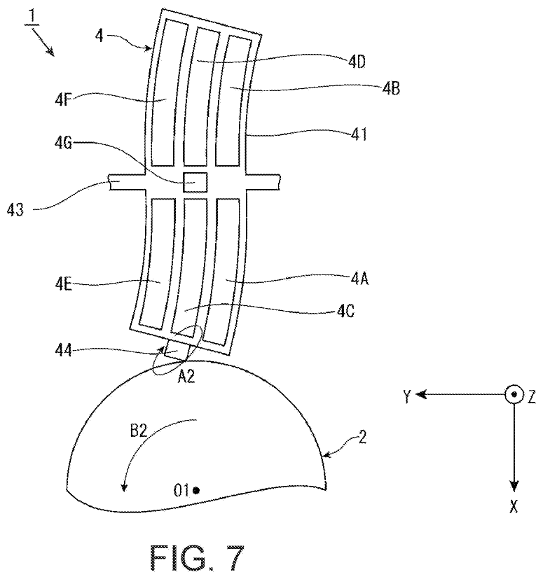

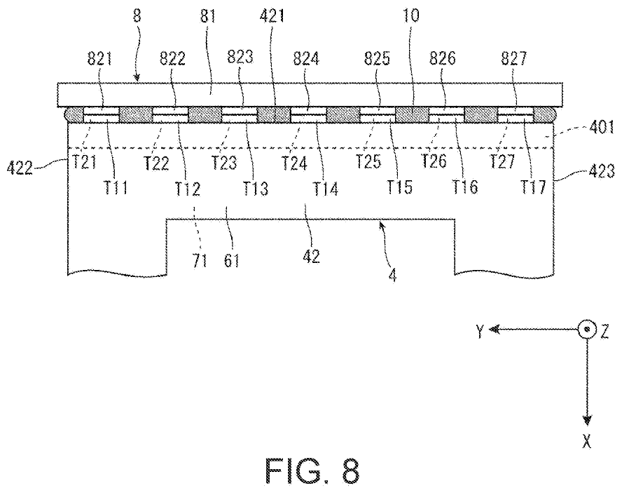

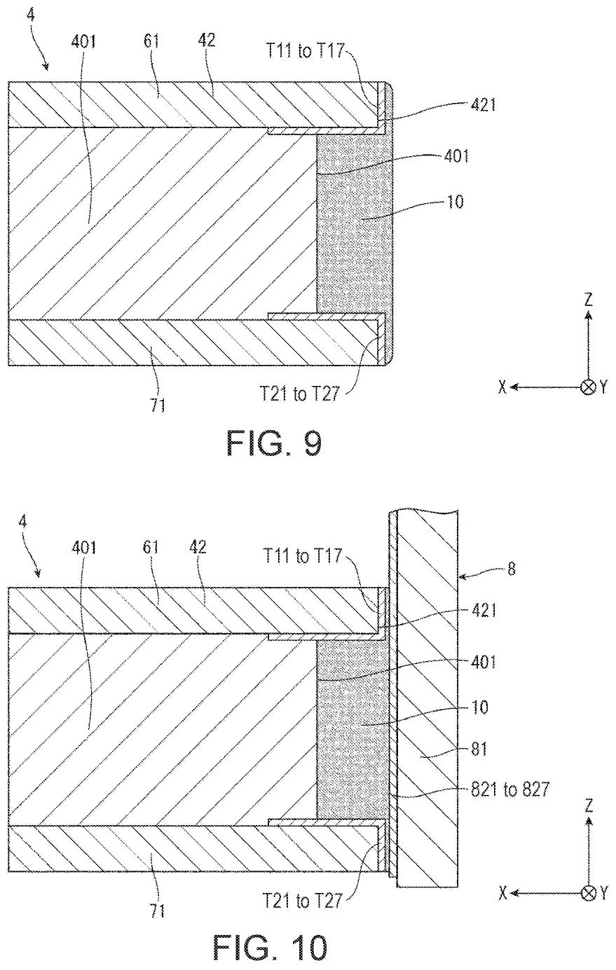

FIG. 1 is a plan view showing a piezoelectric motor according to a first embodiment of the present disclosure. FIG. 2 is a cross-sectional view taken along line A-A, in FIG. 1. FIG. 3 is a cross-sectional view taken along line B-B in FIG. 1. FIG. 4 is a cross-sectional view taken along line C-C in FIG. 1. FIG. 5 is a perspective view illustrating a first side surface of a piezoelectric actuator. FIGS. 6 and 7 are plan views showing a drive state of the piezoelectric actuator. FIG. 8 is a plan view illustrating a bonding section between a wiring substrate and the piezoelectric actuator. FIGS. 9 to 11 are cross-sectional views illustrating a bonding method of the wiring substrate and the piezoelectric actuator.

Hereinafter, for convenience of description, a rotor side of the piezoelectric actuator is also referred to as a “distal end side”, and a side opposite to the rotor is also referred to as a “proximal end side”. In addition, three axes orthogonal to each other are referred to as an X axis, a Y axis, and a Z axis, and a direction along the X axis is referred to as an X axis direction, a direction along the Y axis is referred to as a Y axis direction, and a direction along the Z axis is referred to as a Z axis direction. An arrow side of each axis is also referred to as a “plus side”, and a side opposite to the arrow is also referred to as a “minus side”.

A piezoelectric motor 1 illustrated in FIG. 1 includes a rotor 2 that is rotatable around a rotation axis O1, and an electronic apparatus 100, which is a drive source that rotates the rotor 2. In addition, the electronic apparatus 100 includes a piezoelectric drive device 3 that abuts the outer peripheral surface of the rotor 2, a wiring substrate 8 connected to the piezoelectric drive device 3, and a controller 9 that is electrically connected to the piezoelectric drive device 3 via the wiring substrate 8. In the piezoelectric motor 1, the piezoelectric drive device 3 is driven by control of the controller 9, and the driving force generated by the piezoelectric drive device 3 is transmitted to the rotor 2 to rotate the rotor 2 around the rotation axis O1. However, the configuration of the piezoelectric motor 1 is not particularly limited. For example, a slider that moves linearly may be used instead of the rotor 2.

The piezoelectric drive device 3 includes a piezoelectric actuator 4 as an electronic component and a biasing member 5 that biases the piezoelectric actuator 4 toward the rotor 2. In addition, the piezoelectric actuator 4 includes a laminated body 40 including a vibration section 41, a support section 42 that supports the vibration section 41, and a beam section 43 that connects the vibration section 41 and the support section 42, and includes a convex section 44 that is disposed at a distal end section of the vibration section 41 and that transmits vibration of the vibration section 41 to the rotor 2.

The vibration section 41 has piezoelectric elements 4A to 4F (for drive) and a piezoelectric element 4G (for detection) for detecting vibration of the vibration section 41. The piezoelectric elements 4C and 4D are aligned in the X-axis direction in a central section of the vibration section 41. The piezoelectric elements 4A and 4B are aligned in the X-axis direction to the minus side in the Y-axis direction of the piezoelectric elements 4C and 4D, and the piezoelectric elements 4E and 4F are aligned in the X-axis direction to the plus side in the Y-axis direction of the piezoelectric elements 4C and 4D. Each of the piezoelectric elements 4A to 4F expands and contracts in the X-axis direction by being energized. However, the number and arrangement of the piezoelectric elements for drive are not particularly limited as long as desired vibration can be excited in the vibration section 41.

The piezoelectric element 4G (for detection) is arranged between the piezoelectric elements 4C and 4D. The piezoelectric element 4G receives an external force corresponding to vibration of the vibration section 41 and outputs a detection signal corresponding to the received external force. Therefore, it is possible to detect the vibration state of the vibration section 41 based on the detection signal output from the piezoelectric element 4G. The number and arrangement of the piezoelectric elements for detection are not particularly limited as long as the vibration of the vibration section 41 can be detected. Further, the piezoelectric element for detection may be omitted.

The support section 42 has a U-shape surrounding the vibration section 41 in three directions: both side directions and the proximal end side of the vibration section 41. The support section 42 has a first side surface 421 facing the minus side in the X-axis direction, a second side surface 422 connected to one end side of the first side surface 421 and facing the plus side in the Y-axis direction, and a third side surface 423 connected to the other end side of the first side surface 421 and facing the minus side in the Y-axis direction. The beam section 43 connects the vibration section 41 and the support section 42. The convex section 44 is provided at the tip end section of the vibration section 41, and its tip contacts the outer peripheral surface of the rotor

As shown in FIGS. 2 to 4, the laminated body 40 is formed by bonding two piezoelectric substrates 6 and 7 together. The piezoelectric substrate 6 includes a first substrate 61 and a piezoelectric element layer 62 formed on a back surface (a main surface on the minus side in the Z-axis direction) of the first substrate 61. The piezoelectric element layer 62 includes piezoelectric elements 6A to 6G disposed in the vibration section 41, and spacers 621 disposed in the support section 42 and the beam section 43. The piezoelectric elements 6A to 6G have a configuration in which a piezoelectric body 631 is sandwiched between a pair of electrodes 632 and 633. Among them, the electrode 632 and the piezoelectric body 631 are integrally formed across the piezoelectric elements 6A to 6G, and the electrodes 633 are formed individually for each of the piezoelectric elements 6A to 6G.

Similarly, the piezoelectric substrate 7 includes a second substrate 71 and a piezoelectric element layer 72 formed on a back surface (a main surface on the plus side in the Z-axis direction) of the second substrate 71. In addition, the piezoelectric element layer 72 includes piezoelectric elements 7A to 7G disposed in the vibration section 41, and spacers 721 disposed in the support section 42 and in the beam section 43. The piezoelectric elements 7A to 7G have a configuration in which a piezoelectric body 731 is sandwiched between a pair of electrodes 732 and 733. Among them, the electrode 732 and the piezoelectric body 731 are formed integrally across the piezoelectric elements 7A to 7G, and the electrodes 733 are formed individually for each of the piezoelectric elements 7A to 7G.

Although neither is particularly limited, a silicon substrate, for example, can be used as the first and second substrates 61 and 71. By this, a silicon wafer process (MEMS process) can be used for manufacturing the first and second substrates 61 and 71, and the first and second substrates 61 and 71 can be efficiently manufactured. As the constituent material of the piezoelectric bodies 631 and 731 for example, piezoelectric ceramics such as lead zirconate titanate (PZT), barium titanate, lead titanate, potassium niobate, lithium niobate, lithium tantalate, sodium tungstate, zinc oxide, barium strontium titanate (BST), strontium bismuth tantalate (SBT), lead metaniobate, and scandium lead niobate can be used. In addition, the piezoelectric bodies 631 and 731 can be formed using, for example, a sol-gel method or a sputtering method.

The two piezoelectric substrates 6 and 7 described above are bonded via an adhesive B in a state in which the piezoelectric element layers 62 and 72 face each other. The two piezoelectric elements 6A and 7A overlapping each other constitute the piezoelectric element 4A, the two piezoelectric elements 6B and 7B overlapping each other constitute the piezoelectric element 4B, the two piezoelectric elements 6C and 7C overlapping each other constitute the piezoelectric element 4C, the two piezoelectric elements 6D and 7D overlapping each other constitute the piezoelectric element 4D, the two piezoelectric elements 6E and 7E overlapping each other constitute the piezoelectric element 4E, the two piezoelectric elements 6F and 7F overlapping each other constitute the piezoelectric element 4F, and the two piezoelectric elements 6G and 7G overlapping each other constitute the piezoelectric element 4G.

Further, the thickness of the support section 42 and the thickness of the beam section 43 are made to match the thickness of the vibration section 41 by use of an intermediate layer 400 formed from a laminated body of the two spacers 621 and 721. By this, deflection of the first and second substrates 61 and 71 is suppressed.

As shown in FIG. 5, first terminals T11, T12, T13, T14, T15, T16, T17 are disposed on the first side surface 421 of the first substrate 61. Further, the first terminals T11 to T17 are arranged along the X-axis direction so as to be separated from each other.

The first terminal T11 is electrically connected to the electrode 633 of the piezoelectric element 6A via wiring (not shown), the first terminal T12 is electrically connected to the electrode 633 of the piezoelectric element 6B via wiring (not shown), the first terminal T13 is electrically connected to the electrodes 633 of the piezoelectric elements 6C and 6D via wiring (not shown), the first terminal T14 is electrically connected to the electrode 633 of the piezoelectric element 6E via wiring (not shown), the first terminal T15 is electrically connected to the electrode 633 of the piezoelectric element 6F via wiring (not shown), the first terminal T16 is electrically connected to the electrode 633 of the piezoelectric element 6G via wiring (not shown), and the first terminal T17 is electrically connected to the electrode 632 via wiring (not shown). This enables electrical connection to the piezoelectric elements 6A to 6G via the first terminals T11 to T17.

Similarly, second terminals T21, T22, T23, T24, T25, T26, T27 are disposed on the first side surface 421 of the second substrate 71. The second terminals T21 to T27 are arranged along the X-axis direction to be separated from each other.

The second terminal T21 is electrically connected to the electrode 733 of the piezoelectric element 7A via wiring (not shown), the second terminal T22 is electrically connected to the electrode 733 of the piezoelectric element 7B via wiring (not shown), the second terminal T23 is electrically connected to the electrodes 733 of the piezoelectric elements 7C and 7D via wiring (not shown), the second terminal T24 is electrically connected to the electrode 733 of the piezoelectric element 7E via wiring (not shown), the second terminal T25 is electrically connected to the electrode 733 of the piezoelectric element 7F via wiring (not shown), the second terminal T26 is electrically connected to the electrode 733 of the piezoelectric element 7G via wiring (not shown), and the second terminal T27 is electrically connected to the electrode 732 via wiring (not shown). This enables electrical connection to the piezoelectric elements T21 to T27 via the second terminals 7A to 7G.

In addition, the first terminal T11 and the second terminal T21, the first terminal T12 and the second terminal T22, the first terminal T13 and the second terminal T23, the first terminal T14 and the second terminal T24, the first terminal T15 and the second terminal T25, the first terminal T16 and the second terminal T26, and the first terminal T17 and the second terminal T27 are aligned in the Z-axis direction.

As shown in FIG. 5, the laminated body 40 has a recessed section 401 recessed from the first side surface 421 of the support section 42. The recessed section 401 is located between the first terminals T11 to T17 and the second terminals T21 to T27 in a plan view from the X-axis direction. In addition, the recessed section 401 extends in the X-axis direction, an end on the plus side in the X-axis direction opens to the second side surface 422, and an end on the minus side in the X-axis direction opens to the third side surface 423. By forming the recessed section 401 having both ends opened in this manner, it is possible to>improve reliability of mechanical and electrical connection of the first terminals T11 to T17 and the second terminals T21 to T27 to the wiring substrate 8. This will be described in detail later.

The biasing member 5 urges the piezoelectric actuator 4 toward the rotor 2, and presses the convex section 44 against the outer peripheral surface of the rotor 2. As illustrated in FIG. 1, the biasing member 5 includes a holding section 51 that holds the support section 42 of the piezoelectric actuator 4, a base 52 that fixes the piezoelectric drive device 3 to the stage ST, and a pair of spring groups 53 and 54 that connect the holding section 51 and the base 52. The biasing member 5 urges the piezoelectric actuator 4 toward the rotor 2 by using the restoring force of the spring groups 53 and 54. However, the configuration of the biasing member 5 is not particularly limited as long as the piezoelectric actuator 4 can be biased toward the rotor 2.

The controller 9 is constituted by, for example, a computer, and includes a processor that processes information, a memory that is communicably connected to the processor, and an external interface. In addition, the memory stores programs executable by the processor, and the processor reads and executes the programs stored in the memory. The controller 9 receives a command from a host computer (not illustrated), and drives the piezoelectric actuator 4 based on the command.

For example, when the phase differences of the alternating voltages applied to the piezoelectric elements 4A and 4F, the piezoelectric elements 4B and 4E, and the piezoelectric elements 4C and 4D are controlled and, as shown in FIG. 6, the tip of the convex section 44 is moved in an elliptical motion as indicated by an arrow A1, the rotor 2 starts moving under this elliptical motion and the rotor 2 rotates clockwise as indicated by an arrow B1. Further, as shown in FIG. 7, when the tip of the convex section 44 is moved in an elliptical motion as indicated by an arrow A2, the rotor 2 starts moving under the elliptical motion and the rotor 2 rotates counterclockwise as indicated by an arrow B2.

As shown in FIG. 8, the wiring substrate 8 is a flexible printed wiring substrate. Thus, the degree of freedom in arranging the wiring substrate 8 is improved. The wiring substrate 8 includes a substrate 81 and wiring 821, 822, 823, 824, 825, 826, and 827 disposed on the substrate 81. However, the wiring substrate 8 is not particularly limited, and may be a hard printed wiring substrate.

In addition, the wiring substrate 8 is disposed to oppose the first side surface 421 with the surface on which the wirings 821 to 827 are disposed facing the first side surface 421 side. The wiring substrate 8 is bonded to the piezoelectric actuator 4 via conductive thermosetting adhesive 10 disposed between the wiring substrate 8 and the first side surface 421, and is electrically connected to the first terminals T11 to T17 and to the second terminals T21 to T27.

To be more specific, as shown in FIG. 8, the wiring 821 is electrically connected to the first and second terminals T11 and T21, the wiring 822 is electrically connected to the first and second terminals T12 and T22, the wiring 823 is electrically connected to the first and second terminals T13 and T23, the wiring 824 is electrically connected to the first and second terminals T14 and T24, the wiring 825 is electrically connected to the first and second terminals T15 and T25, the wiring 826 is electrically connected to the first and second terminals T16 and T26, and the wiring 827 is electrically connected to the first and second terminals T17 and T27. In this manner, by bonding the wiring substrate 8 to the support section 42, it is possible to smoothly drive the piezoelectric actuator 4 without inhibiting the vibration of the vibration section 41. In addition, the vibration of the vibration section 41 is less likely to be transmitted to the thermosetting adhesive 10, and fatigue of the thermosetting adhesive 10 can be reduced.

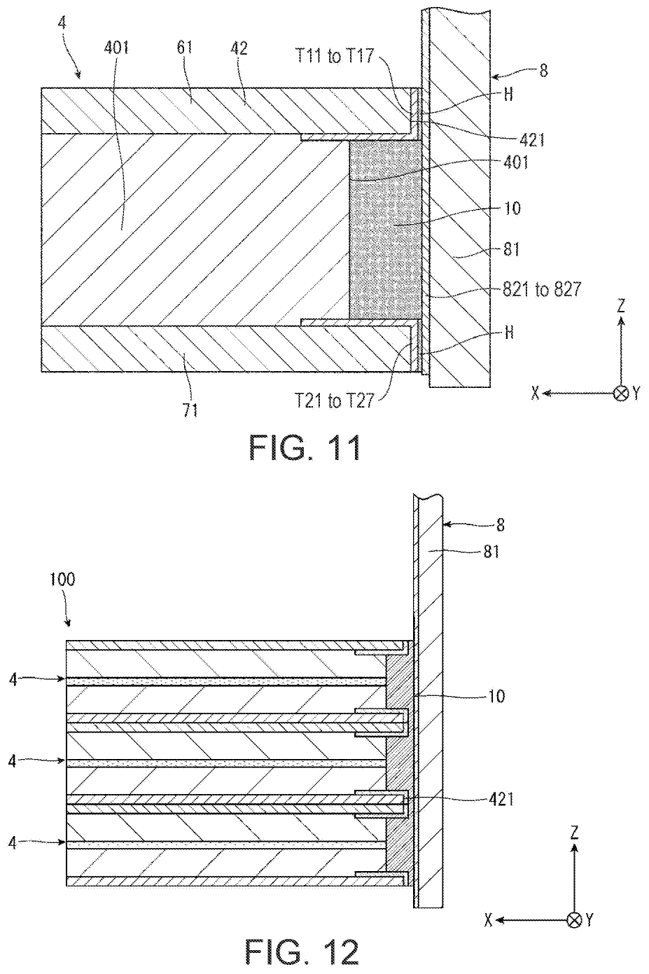

The thermosetting adhesive 10 is, for example, an epoxy-based adhesive containing solder particles (reflow mounting anisotropic conductive paste). By using such an adhesive, the wiring substrate 8 and the support section 42 can be easily mechanically and electrically connected to each other. Specifically, first, as shown in FIG. 9, the recessed section 401 is filled with uncured thermosetting adhesive 10. Next, as shown in FIG. 10, the wiring substrate 8 is bonded to the first side surface 421. Next, the thermosetting adhesive 10 is heated and cured to bond the wiring substrate 8 and the support section 42. When the thermosetting adhesive 10 is heated, as shown in FIG. 11, the solder particles H in the thermosetting adhesive 10 self-aggregate to the first terminals T11 to T17, the second terminals T21 to T27, and the wirings 821 to 827 to form a metallic bond, so that the terminals and the corresponding wirings can be electrically connected while preventing a short circuit between adjacent terminals.

Here, if air remains in the recessed section 401 when the recessed section 401 is filled with the thermosetting adhesive 10, the remaining air expands in the heating process of the thermosetting adhesive 10, and voids (air bubbles) are formed in the thermosetting adhesive 10. When the voids are formed, there is a concern that the bonding strength between the piezoelectric actuator 4 and the wiring substrate 8 is reduced. In addition, when moisture enters the voids, insulation between adjacent terminals is reduced, and there is a possibility that these terminals will short circuit. Thus, the reliability of the mechanical and electrical connection is reduced.

On the other hand, in the present embodiment, both ends of the recessed section 401 are open. Therefore, when the recessed section 401 is filled with the thermosetting adhesive 10, air in the recessed section 401 flows in the X-axis direction and is easily discharged to the outside of the recessed section 401, and it is possible to effectively suppress the occurrence of the above-described voids. Therefore, a decrease in the reliability of mechanical and electrical connection can be suppressed.

The piezoelectric motor 1 as an electronic apparatus has been described above. As described above, the piezoelectric motor 1 includes the piezoelectric actuator 4 as an electronic component including the laminated body 40 in which the intermediate layer 400 is disposed between the first substrate 61 and the second substrate 71, the laminated body 40 including the first side surface 421, the second side surface 422 connected to one side of the first side surface 421, and the third side surface 423 connected to the other side of the first side surface 421, the first terminals T11 to T17 arranged on the first side surface 421 of the first substrate 61, the second terminals T21 to T27 disposed on the first side surface 421 of the second substrate 71, the recessed section 401, which is positioned between the first terminals T11 to T17 and the second terminals 121 to T27 and recessed from the first side surface 421, the wiring substrate 8 disposed to face the first side surface 421, and the thermosetting adhesive 10, which is located between the wiring substrate 8 and the piezoelectric actuator 4 and which mechanically and electrically connects the wiring substrate 8 and the piezoelectric actuator 4 to each other. The recessed section 401 extends along the first side surface 421, and one end of recessed section 401 opens on the second side surface 422 and the other end of the recessed section 401 opens on the third side surface 423. Accordingly, when the uncured thermosetting adhesive 10 is filled into the recessed section 401, air is less likely to remain in the recessed section 401, and voids are less likely to occur in the thermosetting adhesive 10. Therefore, according to the piezoelectric motor 1, a decrease in the reliability of mechanical and electrical connection can be suppressed.

In addition, as described above, the laminated body 40 includes the vibration section 41, the support section 42 supporting the vibration section 41, and the beam section 43 connecting the vibration section 41 and the support section 42, and the support section 42 includes the first side surface 421, the second side surface 422, and the third side surface 423. By this, the wiring substrate 8 is connected to the support section 42. Therefore, it is possible to smoothly drive the piezoelectric actuator 4 without inhibiting the vibration of the vibration section 41. In addition, the vibration of the vibration section 41 is less likely to be transmitted and fatigue of the thermosetting adhesive 10 can be reduced.

Further, as described above, the first substrate 61 and the second substrate 71 are silicon substrates. By this, a silicon wafer process (MEMS process) can be used for manufacturing the first and second substrates 61 and 71, and the first and second substrates 61 and 71 can be efficiently manufactured.

### Second Embodiment

FIG. 12 is a cross-sectional view illustrating an electronic apparatus according to a second embodiment.

The electronic apparatus 100 according to the embodiment is the same as the electronic apparatus 100 according to the first embodiment described above except that a plurality of piezoelectric actuators 4 are stacked. Therefore, in the following description, the present embodiment will be described with a focus on differences from the first embodiment described above, and a description of similar matters will be omitted. In the drawings of the present embodiment, the same reference numerals are given to the same configurations as those of the above-described embodiment.

As shown in FIG. 12, a plurality of piezoelectric actuators 4 are laminated in the piezoelectric drive device 3 of the present embodiment. Accordingly, it is possible to increase the driving force of the piezoelectric drive device 3. The number of piezoelectric actuators 4 that are stacked can be appropriately set in accordance with required driving force.

According to the second embodiment, the same effects as those of the first embodiment described above can be shown.

### Third Embodiment

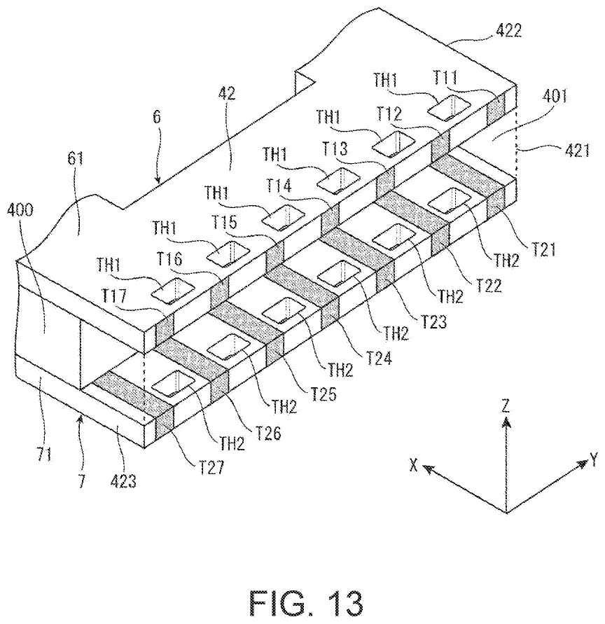

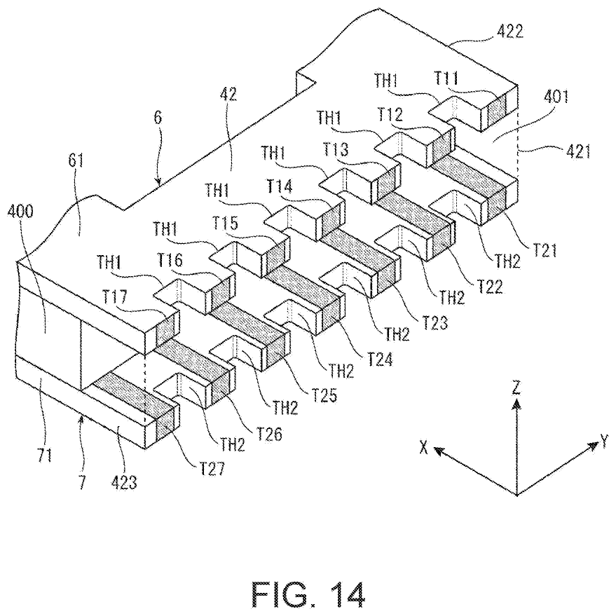

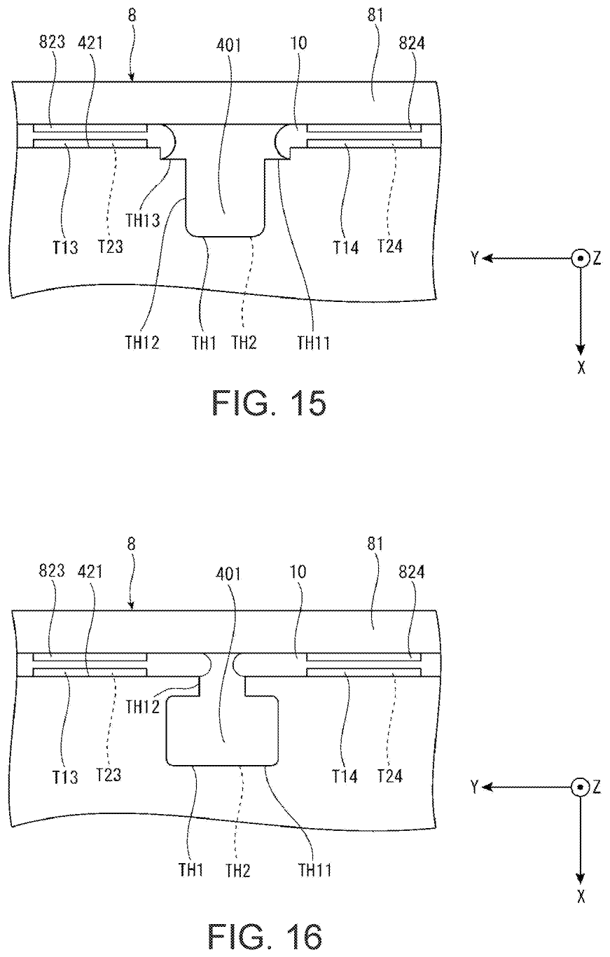

FIG. 13 is a perspective view illustrating a first side surface of a piezoelectric actuator according to a third embodiment. FIG. 14 is a perspective view showing a modification of the piezoelectric actuator. FIGS. 15 and 16 are plan views showing modifications of the piezoelectric actuator.

The piezoelectric actuators 4 of the present embodiment are the same as the piezoelectric actuators 4 of the first embodiment described above, except that first and second through holes TH1 and TH2 are formed. Therefore, in the following description, the present embodiment will be described with a focus on differences from the first embodiment described above, and a description of similar matters will be omitted. In each drawing of the present embodiment, the same reference numerals are given to the same configurations as those of the above-described embodiment.

As shown in FIG. 13, the first substrate 61 in the piezoelectric actuator 4 of the present embodiment has first through holes TH1 that communicate with the recessed section 401. Similarly, the second substrate 71 has second through holes TH2 communicating with the recessed section 401. In this way, by forming the first and second through holes TH1 and TH2, which communicate with the recessed section 401, in the first and second substrates 61 and 71, air in the recessed section 401 is discharged to the outside of the recessed section 401 also from the first and second through holes TH1 and TH2. Accordingly, when the uncured thermosetting adhesive 10 is filled into the recessed section 401, air is even less likely to remain in the recessed section 401, and voids are even less likely to occur in the thermosetting adhesive 10. Therefore, according to the piezoelectric motor 1, a decrease in the reliability of mechanical and electrical connection can be even more suppressed.

Furthermore, the first through holes TH1 are disposed between adjacent ones of the first terminals T11 to T17. That is, the first through holes TH1 are respectively disposed between the first terminals T11 and T12, between the first terminals T12 and T13, between the first terminals T13 and T14, between the first terminals T14 and T15, between the first terminals T15 and T16, and between the first terminals T16 and T17. Similarly, the second through holes TH2 are disposed between adjacent ones of the second terminals T21 to T27. That is, the second through holes TH2 are disposed between the second terminals T21 and T22, between the second terminals T22 and T23, between the second terminals T23 and T24, between the second terminals T24 and T25, between the second terminals T25 and T26, and between the second terminals T26 and T27. According to such a configuration, the above-described effects become more striking. In particular, voids are less likely to be generated in a region between adjacent terminals, and thus a decrease in reliability of electrical connection can be more effectively suppressed.

In the above-described second embodiment, the first substrate 61 has first through holes TH1 communicating with the recessed section 401 as described above. Therefore, air in the recessed section 401 is also discharged from the first through holes TH1 to the outside of the recessed section 401. Accordingly, when the uncured thermosetting adhesive 10 is filled into the recessed section 401, air is even less likely to remain in the recessed section 401, and voids are even less likely to occur in the thermosetting adhesive 10.

As described above, the first substrate 61 includes the plurality of first terminals T11 to T17 arranged along the first side surface 421, and the first through holes TH1 are arranged between adjacent ones of the first terminals T11 to T17. Accordingly, when the uncured thermosetting adhesive 10 is filled into the recessed section 401, air is even less likely to remain in the recessed section 401, and voids are even less likely to occur in the thermosetting adhesive 10. In particular, voids are less likely to be generated in a region between adjacent first terminals T11 to T17, and thus a decrease in reliability of electrical connection can be more effectively suppressed.

Further, as described above, the second substrate 71 has the second through holes TH2 communicating with the recessed section 401. Therefore, air in the recessed section 401 is also discharged from the second through holes TH2 to the outside of the recessed section 401. Accordingly, when the uncured thermosetting adhesive 10 is filled into the recessed section 401, air is even less likely to remain in the recessed section 401, and voids are even less likely to occur in the thermosetting adhesive 10.

As described above, the second substrate 71 includes the plurality of second terminals T21 to T27 arranged along the first side surface 421, and the second through holes TH2 are arranged between adjacent second terminals T21 to T27. Accordingly, when the uncured thermosetting adhesive 10 is filled into the recessed section 401, air is even less likely to remain in the recessed section 401, and voids are even less likely to occur in the thermosetting adhesive 10. In particular, voids are less likely to be generated in a region between adjacent second terminals T21 to T27, and thus a decrease in reliability of electrical connection can be more effectively suppressed.

According to the third embodiment described above, the same effects as those of the first embodiment described above can be shown. However, the third embodiment is not limited to this and, for example, at least one of the first terminals T11 to T17 and the second terminals T21 to T27 may be omitted.

Further, for example, as shown in FIG. 14, each first and second through hole TH1, TH2 may open on the first side surface 421. That is, each side first and second through hole TH1 and TH2 may be a groove formed in the first side surface 421.

Further, for example, as shown in FIG. 15, the first through holes TH1 may have a widening section TH11 that opens to the first side surface 421, and a width reduction section TH12 that opens on the widening section TH11 and that is narrower than the widening section TH11. According to such a configuration, a step TH13 is formed by the widening section TH11 in between the first side surface 421 and the width reduction section TH12. The step TH13 functions as an anchor, and it is possible to suppress the entry of thermosetting adhesive 10 into the first through holes TH1. Therefore, the first through holes TH1 are less likely to be blocked, and air in the recessed section 401 can be more reliably released via the first through hole TH1. The same applies to the second through holes TH2.

Further, for example, as shown in FIG. 16, the first through holes TH1 may have a width reduction section TH12 that opens on the first side surface 421, and a widening section TH11 that opens on the width reduction section TH12 and that is wider than the width reduction section TH12. According to such a configuration, it is possible to suppress the opening size to the first side surface 421 to be small, and thus it is possible to suppress entry of thermosetting adhesive 10 into the first through holes TH1. Therefore, the first through holes TH1 are less likely to be blocked, and air in the recessed section 401 can be more reliably released via the first through hole TH1. The same applies to the second through holes TH2.

### Fourth Embodiment

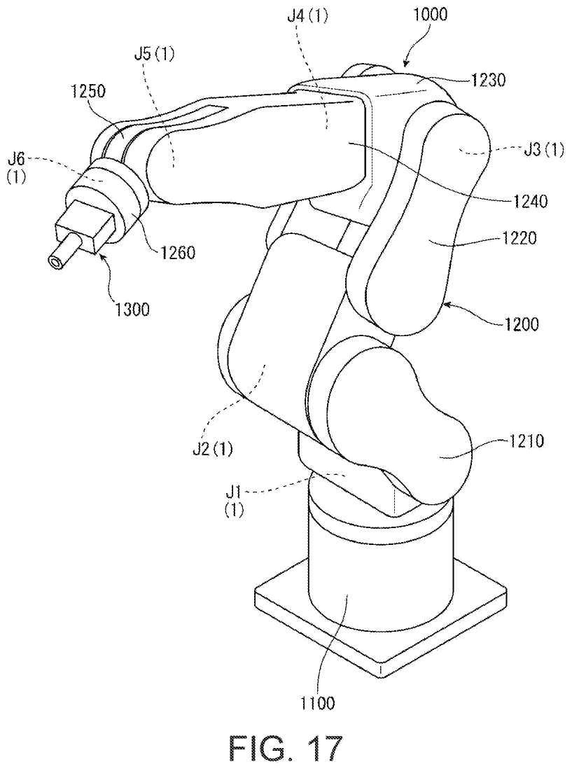

FIG. 17 is a perspective view illustrating a robot according to a fourth embodiment.

A robot 1000 shown in FIG. 17 can perform work such as supply, removal, conveyance, and assembly of precision equipment and components constituting the precision equipment. The robot 1000 is, for example, a robot that performs work such as supply, removal, conveyance, and assembly of precision equipment and components constituting the precision equipment. However, the use of the robot 1000 is not particularly limited.

The robot 1000 is a six axis robot having six rotation axes. The robot 1000 includes a base 1100 and a robot arm 1200 rotatably coupled to the base 1100, and an end effector 1300 is attached to a distal end section of the robot arm 1200.

The robot arm 1200 is a robotic arm in which a plurality of arms 1210, 1220, 1230, 1240, 1250, and 1260 are rotatably connected, and includes six joints J1 to J6. The joints J2, J3, and J5 are bending joints, and the joints J1, J4, and J6 are torsional joints. An electronic apparatus 100 serving as a drive source is installed in each joint J1, J2, J3, J4, J5, and J6. Therefore, the robot 1000 can enjoy the effects of the electronic apparatus 100 and can exhibit excellent reliability.

However, the robot 1000 is not particularly limited, and may have at least one joint. The electronic apparatus 100 may be disposed in at least one of the joints J1, J2, J3, J4, J5, or J6.

The robot 1000 has been described above. As described above, the robot 1000 includes at least one of the joints J1, J2, J3, J4, J5, or J6 and the electronic apparatus 100 that drives the joints J1, J2, J3, J4, J5, and J6. The electronic apparatus 100 includes the piezoelectric actuator 4 as an electronic component including the laminated body 40 in which the intermediate layer 400 is disposed between the first substrate 61 and the second substrate 71, the laminated body 40 including the first side surface 421, the second side surface 422 connected to one side of the first side surface 421, and the third side surface 423 connected to the other side of the first side surface 421, the first terminals T11 to T17 arranged on the first side surface 421 of the first substrate 61, the second terminals T21 to T27 disposed on the first side surface 421 of the second substrate 71, the recessed section 401, which is positioned between the first terminals T11 to T17 and the second terminals T21 to T27 and recessed from the first side surface 421, the wiring substrate 8 disposed to face the first side surface 421, and the thermosetting adhesive 10, which is located between the wiring substrate 8 and the piezoelectric actuator 4 and which mechanically and electrically connects the wiring substrate 8 and the piezoelectric actuator 4 to each other. The recessed section 401 extends along the first side surface 421, and one end of recessed section 401 opens on the second side surface 422 and the other end of the recessed section 401 opens on the third side surface 423. Accordingly, when the uncured thermosetting adhesive 10 is filled into the recessed section 401, air is less likely to remain in the recessed section 401, and voids are less likely to occur in the thermosetting adhesive 10. Therefore, according to the electronic apparatus 100, it is possible to suppress a decrease in reliability of mechanical and electrical connection. The robot 1000 using such an electronic apparatus 100 can exhibit excellent reliability.

### Fifth Embodiment

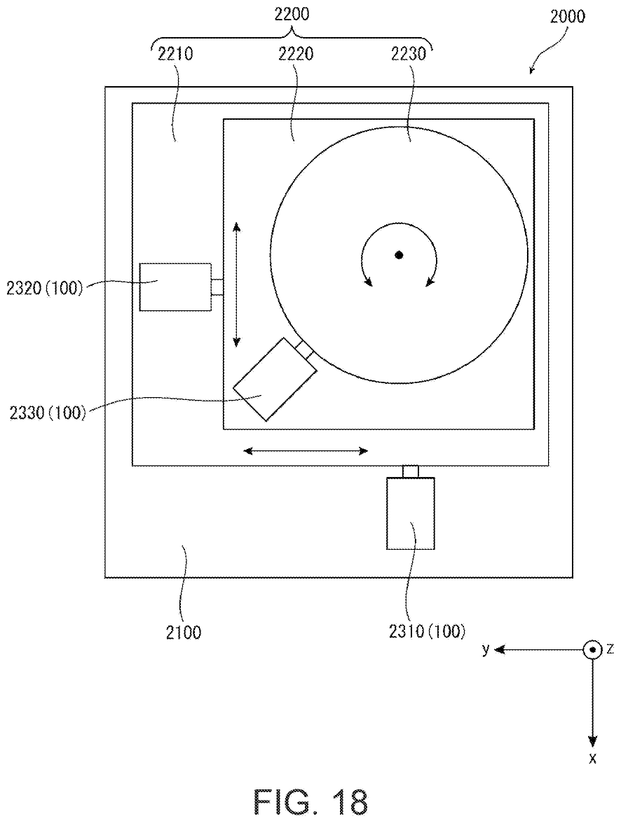

FIG. 18 is a plan view showing a motion stage according to a fifth embodiment.

Note that for convenience of explanation, hereinafter three axes orthogonal to each other are referred to as an x axis, a y axis, and a z axis, and a direction along the x axis is referred to as an x axis direction, a direction along they axis is referred to as a y axis direction, and a direction along the z axis is referred to as a z axis direction.

The motion stage 2000 shown in FIG. 18 includes a base 2100 and a movable section 2200 that moves with respect to the base 2100. The movable section 2200 includes a first movable section 2210 that moves in the y-axis direction with respect to the base 2100, a second movable section 2220 that moves in the x-axis direction with respect to the first movable section 2210, and a third movable section 2230 that moves around the z-axis with respect to the second movable section 2220. The motion stage 2000 includes an electronic apparatus 2310 that moves the first movable section 2210 with respect to the base 2100, an electronic apparatus 2320 that moves the second movable section 2220 with respect to the first movable section 2210, and an electronic apparatus 2330 that moves the third movable section 2230 with respect to the second movable section 2220. The electronic apparatus 100 is used as the electronic apparatuses 2310, 2320, and 2330. Therefore, the motion stage 2000 can enjoy the effects of the electronic apparatus 100 and can exhibit excellent reliability.

However, the motion stage 2000 is not particularly limited. For example, one or two of the first, second, and third movable sections 2210, 2220, and 2230 may be omitted. The electronic apparatus 100 does not need to be used in all of the first, second, and third drive sources 2310, 2320, and 2330, and may be used in at least one of them.

The motion stage 2000 has been described above. As described above, the, motion stage 2000 includes the base 2100, the movable section 2200 connected to the base 2100, and the electronic apparatus 100 that moves the movable section 2200 with respect to the base 2100. The electronic apparatus 100 includes the piezoelectric actuator 4 as an electronic component including the laminated body 40 in which the intermediate layer 400 is disposed between the first substrate 61 and the second substrate 71, the laminated body 40 including the first side surface 421, the second side surface 422 connected to one side of the first side surface 421, and the third side surface 423 connected to the other side of the first side surface 421, the first terminals T11 to T17 arranged on the first side surface 421 of the first substrate 61, the second terminals T21 to T27 disposed on the first side surface 421 of the second substrate 71, the recessed section 401, which is positioned between the first terminals T11 to T17 and the second terminals T21 to T27 and recessed from the first side surface 421, the wiring substrate 8 disposed to face the first side surface 421, and the thermosetting adhesive 10, which is located between the wiring substrate 8 and the piezoelectric actuator 4 and which mechanically and electrically connects the wiring substrate 8 and the piezoelectric actuator 4 to each other. The recessed section 401 extends along the first side surface 421, and one end of recessed section 401 opens on the second side surface 422 and the other end of the recessed section 401 opens on the third side surface 423. Accordingly, when the uncured thermosetting adhesive 10 is filled into the recessed section 401, air is less likely to remain in the recessed section 401, and voids are less likely to occur in the thermosetting adhesive 10. Therefore, according to the electronic apparatus 100, it is possible to suppress a decrease in reliability of mechanical and electrical connection. The motion stage 2000 using such an electronic apparatus 100 can exhibit excellent reliability. Although the electronic apparatus, the robot, and the motion stage according to the present disclosure have been described above based on the illustrated embodiments, the present disclosure is not limited thereto, and the configuration of each unit can be replaced with an arbitrary configuration having the same function.

In addition, any other configuration may be added to the present disclosure. Further, the embodiments may be appropriately combined. In the above-described embodiments, the configuration In which the piezoelectric motor 1 is applied to the robot 1000 or the motion stage 2000 has been described. However, the piezoelectric motor 1 can be applied to various electronic apparatuses requiring a driving force other than the robot 1000 and the motion stage 2000, for example, a printer, a projector, and the like. In the above-described embodiments, the configuration in which the electronic apparatus is applied to the piezoelectric motor 1 has been described, but the electronic apparatus is not limited to the piezoelectric motor 1.

What is claimed is:

1. An electronic apparatus comprising:
an electronic component including:
a laminated body in which an intermediate layer is disposed between a first substrate and a second substrate, the laminated body including a first side surface, a second side surface connected to one side of the first side surface, and a third side surface connected to the other side of the first side surface,
a first terminal disposed on the first side surface of the first substrate,
a second terminal disposed on the first side surface of the second substrate, and
a recessed section located between the first terminal and the second terminal and recessed from the first side surface;
a wiring substrate disposed facing the first side surface; and
a thermosetting adhesive that is located between the wiring substrate and the electronic component and that mechanically and electrically connects the wiring substrate and the electronic component to each other,
wherein the recessed section extends along the first side surface and one end of the recessed section opens on the second side surface and the other end of the recessed section opens on the third side surface.

2. The electronic apparatus according to claim 1, wherein
the first substrate has a first through hole communicating with the recessed section.

3. The electronic apparatus according to claim 2, wherein
the first substrate has a plurality of the first terminals arranged along the first side surface and
the first through hole is disposed between a pair of adjacent first terminals.

4. The electronic apparatus according to claim 1, wherein
the second substrate has a second through hole communicating with the recessed section.

5. The electronic apparatus according to claim 4, wherein
the second substrate has a plurality of the second terminals arranged along the first side surface and
the second through hole is disposed between a pair of adjacent second terminals.

6. The electronic apparatus according to claim 1, wherein
the laminated body includes a vibration section, a support section supporting the vibration section, and a beam section connecting the vibration section and the support section to each other and
the support section includes the first side surface, the second side surface, and the third side surface.

7. The electronic apparatus according to claim 1, wherein
the first substrate and the second substrate are silicon substrates.

8. A robot comprising:
at least one joint and
an electronic apparatus for driving the joint, the electronic apparatus including:
an electronic component including:
a laminated body in which an intermediate layer is disposed between a first substrate and a second substrate, the laminated body including a first side surface, a second side surface connected to one side of the first side surface, and a third side surface connected to the other side of the first side surface,
a first terminal disposed on the first side surface of the first substrate,
a second terminal disposed on the first side surface of the second substrate, and
a recessed section located between the first terminal and the second terminal and recessed from the first side surface;
a wiring substrate disposed facing the first side surface; and
a thermosetting adhesive that is located between the wiring substrate and the electronic component and that mechanically and electrically connects the wiring substrate and the electronic component to each other,
wherein the recessed section extends along the first side surface and one end of the recessed section opens on the second side surface and the other end of the recessed section opens on the third side surface.

9. A motion stage comprising:
a base;
a movable section connected to the base; and
an electronic apparatus configured to move the movable section with respect to the base the electronic apparatus including:
an electronic component including:
a laminated body in which an intermediate layer is disposed between a first substrate and a second substrate, the laminated body including a first side surface, a second side surface connected to one side of the first side surface, and a third side surface connected to the other side of the first side surface,
a first terminal disposed on the first side surface of the first substrate
a second terminal disposed on the first side surface of the second substrate, and
a recessed section located between the first terminal and the second terminal and recessed from the first side surface;
a wiring substrate disposed facing the first side surface; and
a thermosetting adhesive that is located between the wiring substrate and the electronic component and that mechanically and electrically connects the wiring substrate and the electronic component to each other,
wherein the recessed section extends along the first side surface and one end of the recessed section opens on the second side surface and the other end of the recessed section opens on the third side surface.
